(19) United States
(12) Patent Application Publication
(10) Pub. No.: US 2017/0316922 A1
(43) Pub. Date: Nov. 2, 2017

(54) GAS SUPPLY STRUCTURE FOR INDUCTIVELY COUPLED PLASMA PROCESSING APPARATUS

(71) Applicant: VNI SOLUTION Co., LTD., Daejeon-si (KR)

(72) Inventor: Saeng Hyun CHO, Suwon-si (KR)

(73) Assignee: VNI SOLUTION Co., LTD., Daejeon-si (KR)

(21) Appl. No.: 15/152,129

(22) Filed: May 11, 2016

(30) Foreign Application Priority Data
Apr. 27, 2016 (KR) 10-2016-0051723

(51) Int. Cl. H01J 37/32

(52) U.S. Cl. CPC H01J 37/32449; H01J 37/32834; H01J 37/3211; H01J 2237/3344; H01J 2237/3323

(57) ABSTRACT

A gas supply structure for an inductively coupled plasma (ICP) processing apparatus that includes a main container 10 that houses a substrate to be processed S to perform plasma processing, a substrate mounting unit 20 on which the substrate to be processed S is mounted in the main container 10, an exhaust system 30 that discharges gas from inside of the main container 10, one or more dielectric windows 100 that form an upper window of the main container 10, and one or more RF antennas 40 which are installed to correspond to the dielectric windows 100 outside the main container 10 and to which RF power is applied to form induced electric field in the main container 10, comprising a first diffusion plate 210 that firstly diffuses the processing gas and is connected with a processing gas supplying pipe 300, and a second diffusion plate 220 that diffuses the processing gas diffused by the first diffusion plate 210 into the main container 10 and is installed under the first diffusion plate 210, wherein the second diffusion plate 220 is formed at at least a part of the lower surface of the dielectric windows 100, is provided, so it is possible to perform injection control of the processing gas onto the plane surface of the substrate to be processed and uniform substrate processing.

### CROSS-REFERENCE TO RELATED APPLICATION

This application claims priority to Korean Patent Application No. 10-2016-0051723 filed on Apr. 27, 2016 and all the benefits accruing therefrom under 35 U.S.C. §119, the contents of which are incorporated by reference in their entirety.

### BACKGROUND OF THE INVENTION

### 1. Field of the Invention

The present disclosure relates to an inductively coupled plasma processing apparatus that performs substrate processing, such as substrate etching or deposition.

### 2. Background of the Invention

In order to perform predetermined processing on a substrate in the manufacturing process of an liquid crystal display (LCD) or an organic light-emitting diode (OLED), various plasma processing apparatuses such as a plasma etching apparatus or plasma CVD deposition apparatus are used. A capacitively coupled plasma processing apparatus has been typically used as such a plasma processing apparatus, but in recent, an inductively coupled plasma (ICP) processing apparatus that has a big advantage of being capable of obtaining high-density plasma at high degree of vacuum is receiving attention.

The ICP processing apparatus disposes an RF antenna outside the dielectric window of a main container that houses a substrate to be processed, and applies RF power to the RF antenna simultaneously with supplying a processing gas into the main container to generate ICP in the main container and perform predetermined plasma processing on the substrate to be processed by the ICP. As the RF antenna of the ICP processing apparatus, a planar antenna that has a vortex pattern is being mostly used.

However, with a recent increase in the size of a substrate, there is a need for an increase in the size of a plasma processing apparatus in order to process larger substrate that excesses 1 m in the length of one side thereof.

Thus, as the ICP processing apparatus for processing the large substrate also increases in size, the variation of plasma density on the plane of the substrate to be processed increases and thus there is limitation that it is difficult to perform uniform substrate processing.

In particular, injection structure of processing gas has great influence on the variation of the variation of plasma density, and in the prior arts there are a gas injection structure in which the processing gas is injected from the side wall of the main container, and a gas injection structure in which the processing gas is injected through the gas injection path formed in the supporting member supporting the dielectric window.

However, the above gas injection structures, have a problem in that uniform gas injection to the large substrate or gas injection control is difficult, which greaten the variation of plasma density, and eventually makes uniform substrate processing impossible.

### SUMMARY OF THE INVENTION

The present disclosure provides a gas supply structure for an inductively coupled plasma (ICP) processing apparatus capable of injection control of the processing gas onto the plane surface of the substrate to be processed and uniform substrate processing by installing a gas injection structure at at least a portion of the dielectric window.

To achieve these and other advantages and in accordance with the purpose of the present invention, there is provided a gas supply structure for an inductively coupled plasma (ICP) processing apparatus that includes a main container 10 that houses a substrate to be processed S to perform plasma processing, a substrate mounting unit 20 on which the substrate to be processed S is mounted in the main container 10, an exhaust system 30 that discharges gas from inside of the main container 10, one or more dielectric windows 100 that form an upper window of the main container 10, and one or more RF antennas 40 which are installed to correspond to the dielectric windows 100 outside the main container 10 and to which RF power is applied to form induced electric field in the main container 10, comprising a first diffusion plate 210 that firstly diffuses the processing gas and is connected with a processing gas supplying pipe 300, and a second diffusion plate 220 that diffuses the processing gas diffused by the first diffusion plate 210 into the main container 10 and is installed under the first diffusion plate 210, wherein the second diffusion plate 220 is formed at at least a part of the lower surface of the dielectric windows 100.

According to an embodiment, a plurality of the dielectric windows 100 may have a rectangular plane shape, and the plurality of the dielectric windows 100 may be installed on the upper end of the main container 10 and the edges of the plurality of the dielectric windows 100 may be supported by a supporting member 230 so that the plurality of the dielectric windows 100 are arranged in a lattice pattern.

And in at least a part of the plurality of the dielectric windows 100, the dielectric window 100 may be formed by all the first diffusion plate 210 and the second diffusion plate 220, and the first diffusion plate 210 and the second diffusion plate 220 may be installed having a gap with each other in an upper and lower direction.

According to an embodiment, in at least a part of the plurality of the dielectric windows 100, the second diffusion plate 220 may be formed in a part of the plane surface of the dielectric window 100.

And the gas supply structure, wherein one of the first diffusion plate 210 and the second diffusion plate 220 is integratedly formed with the dielectric window 100, and the first diffusion plate 210 and the second diffusion plate 220 are installed having a gap with each other in an upper and lower direction.

According to an embodiment, the dielectric window 100 may be formed with a groove which is inserted with at least a portion of the RF antenna 40.

According to an embodiment, one or more ribs 240 having the same material as that of the dielectric window 100 may be formed at the upper surface of the dielectric window 100.

According to an embodiment, a diffusion space forming member 320 that forms a processing gas diffusion space in which the processing gas is diffused in advance and is connected to a processing gas supply pipe 300, may be further installed.

And a diffusion assistance member 310 for the processing gas diffusion formed with a plurality of injection holes 311 for injecting the processing gas into the processing gas diffusion space, the diffusion assistance member 310 being connected to the processing gas supply pipe 300, may be further installed.

According to the present invention, it is possible to perform injection control of the processing gas onto the plane surface of the substrate to be processed and uniform substrate processing.

Concretely, it is possible to perform injection control of the processing gas into the main container and uniform substrate processing by the gas supply structure in which a plurality of the diffusion plates are installed or formed in at least a portion of the dielectric window.

According to the present invention, since one or more ribs are integrated or bonded, enhancing the structural strength so that the strength of the dielectric window is enhanced when the size of the dielectric window increases in order to process the large substrate, it is possible to prevent the deflection or deformation.

In particular, the use of the relatively thinner dielectric window makes the vertical distance of the RF antenna to the inside of the main container less so that it is possible to enhance the efficiency of the substrate processing.

### BRIEF DESCRIPTION OF THE DRAWINGS

FIG. 1 is a cross-sectional view showing an inductively coupled plasma processing apparatus according to an embodiment of the present invention.

FIG. 2 is a plan view showing a dielectric window and a supporting member in FIG. 1.

FIG. 3 is a cross-sectional view taken along line III-III in FIG. 2.

FIGS. 4 to 6 are cross-sectional views showing modified examples of FIG. 3.

FIG. 7 is a cross-sectional view showing another modified example of FIG. 3.

FIG. 8 is a cross-sectional view showing an inductively coupled plasma processing apparatus according to another embodiment of the present invention.

FIG. 9 is an enlarged view showing the enlarged A portion in FIG. 8.

FIG. 10 is a plan view showing a dielectric window and a supporting member in FIG. 8.

### DETAILED DESCRIPTION OF THE INVENTION

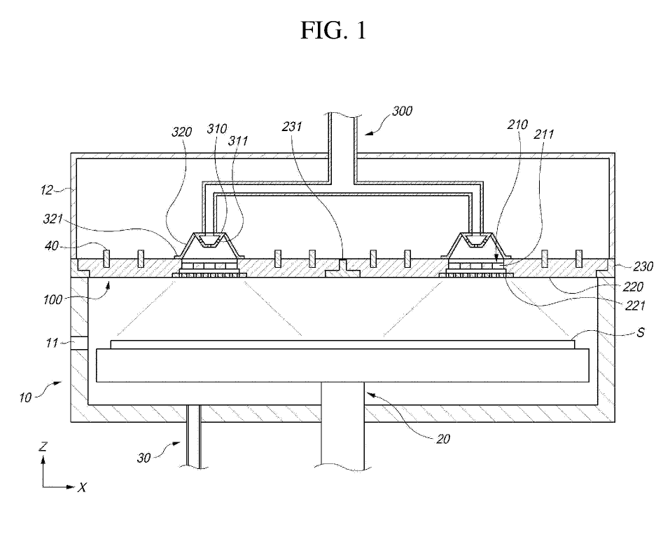

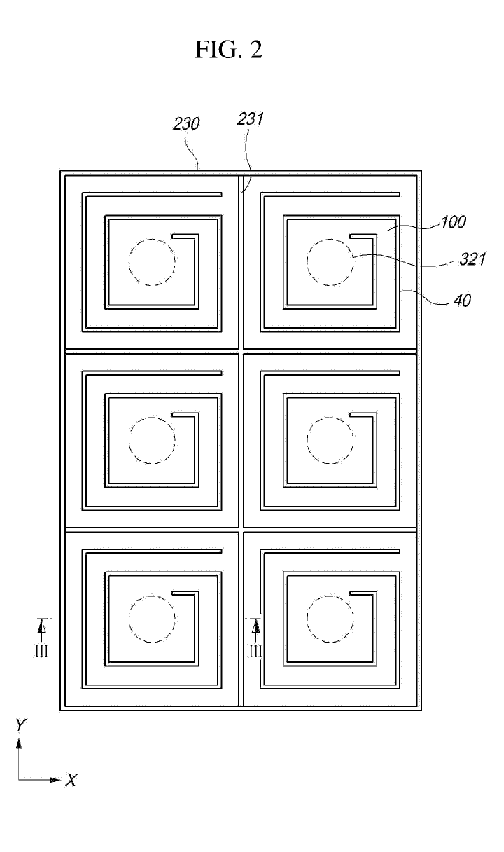

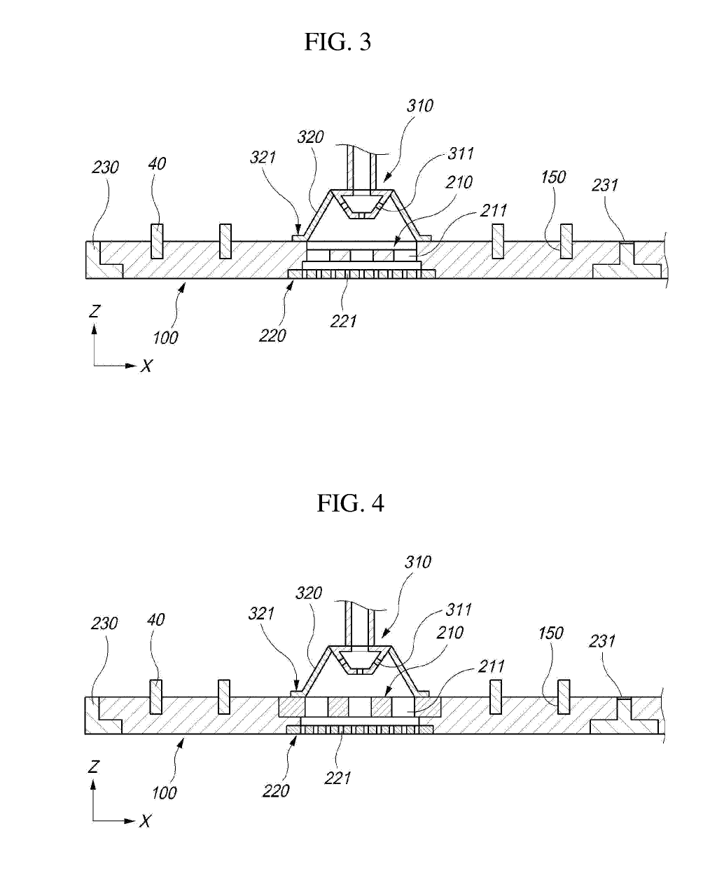

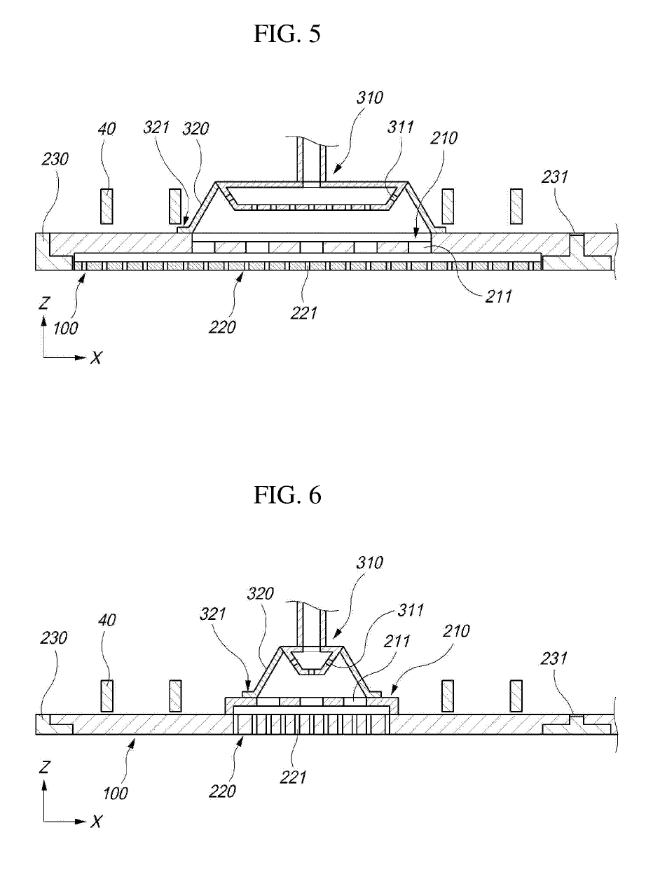

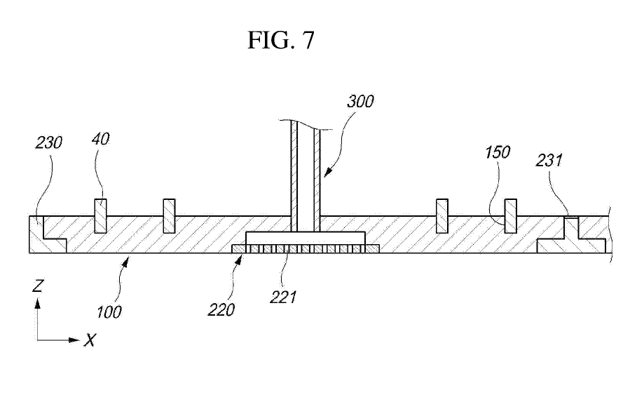

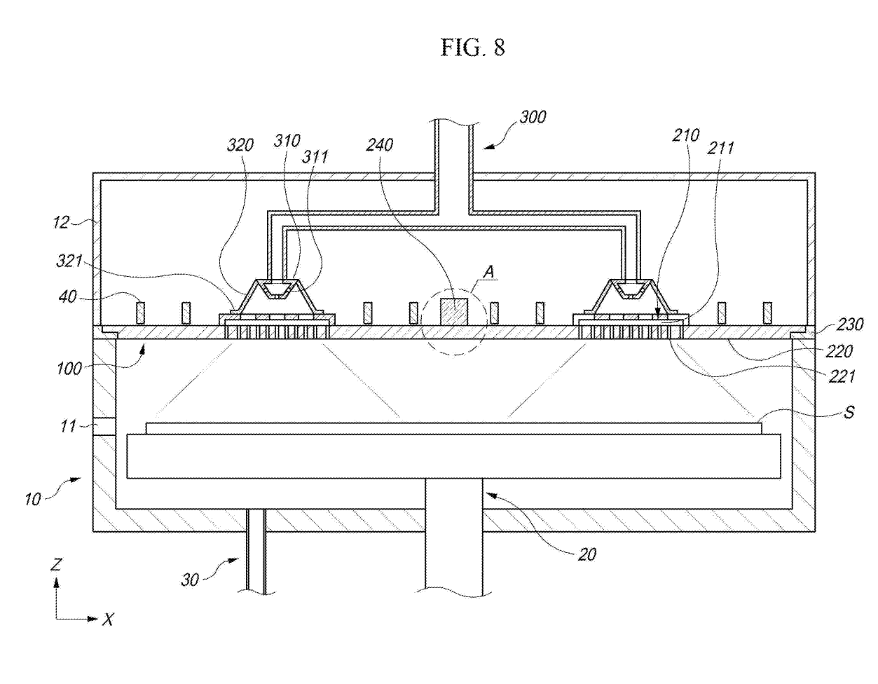

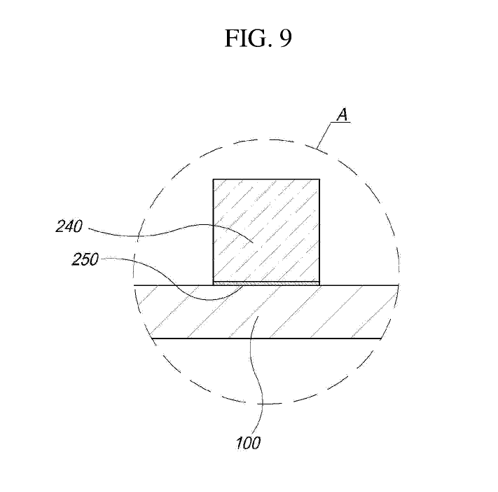

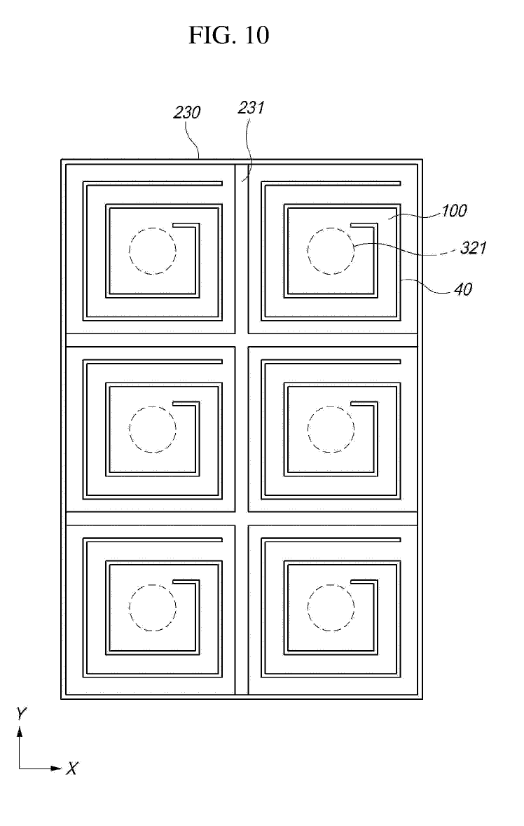

In the following, an embodiment of the present invention is described with reference to the accompanying drawings. FIG. 1 is a cross-sectional view showing an inductively coupled plasma processing apparatus according to an embodiment of the present invention, FIG. 2 is a plan view showing a dielectric window and a supporting member in FIG. 1, FIG. 3 is a cross-sectional view taken along line III-III in FIG. 2, FIGS. 4 to 6 are cross-sectional views showing modified examples of FIG. 3, FIG. 7 is a cross-sectional view showing another modified example of FIG. 3, FIG. 8 is a cross-sectional view showing an inductively coupled plasma processing apparatus according to another embodiment of the present invention, FIG. 9 is an enlarged view showing the enlarged A portion in FIG. 8, FIG. 10 is a plan view showing a dielectric window and a supporting member in FIG. 8.

The ICP processing apparatus according to an embodiment of the present invention includes a main container 10 that houses a substrate to be processed S to perform plasma processing, a substrate mounting unit 20 on which the substrate to be processed S is mounted in the main container 10, an exhaust system 30 that discharges gas from the inside of the main container 10, one or more dielectric windows 100 that form the upper window of the main container 10, and one or more RF antennas 40 which are installed to correspond to the dielectric windows 100 outside the main container 10 and to which RF power is applied to form induced electric field in the main container 10.

The apparatus may be used in order to perform a substrate processing process, such as etching a metal layer, ITO layer, oxide layer or the like or forming a disposition layer when forming a thin film transistor on the substrate to be processed in manufacturing e.g., a liquid crystal display (LCD) or organic light-emitting diode (OLED).

Here, the substrate S to be processed may generally have a rectangular shape and be 1 m or more in the size of one side.

The main container 10 is a component that houses the substrate to be processed S to form an inner space in which plasma processing is performed.

The main container 10 may have a quadrilateral barrel that is formed from conductive material, e.g., aluminum having anodized inner wall, be assembled and dissembled, and be grounded by a ground line (not shown).

In addition, a gate for introducing/withdrawing the substrate S and a gate valve (not shown) for opening/closing the gate are installed on the sidewall of the main container 10.

The substrate mounting unit 20 may be formed from conductive material, e.g., aluminum having an anodized surface. The substrate S mounted on the substrate mounting unit 22 may attached to the substrate mounting unit 22 by an electrostatic chuck (not shown).

In addition, the substrate mounting unit 22 may be connected to a RF power source (not shown) via a matcher (not shown) by a power supply rod (not shown).

The RF power source may apply bias RF power, e.g., RF power having a frequency of 6 MHz to the substrate mounting unit 22 during the plasma processing. By the bias RF power, ions in the plasma generated in the main container 10 may effectively enter the substrate S.

Also, in order to control the temperature of the substrate S, a temperature control device that includes a heating device, such as a ceramic heater or a refrigerant flow path, and a temperature sensor (that are not shown) are installed in the substrate mounting unit 22.

The exhaust system 30 is a component that discharges gas from the inside of the main container 10.

The exhaust system 30 includes an exhaust pipe to which an exhaust device including a vacuum pump is connected, in the bottom of the main container 10, the gas from the main container 10 is exhausted by the exhaust device, and the inside of the main container 10 is set and maintained to be predetermined vacuum atmosphere (e.g., 1.33 Pa) during the plasma processing.

The RF antenna 40 is a component which is installed to correspond to the dielectric window 100 outside the main container 10 and to which RF power is applied to form induced electric field in the main container 10.

The RF antenna 40 may be installed within a certain distance from the dielectric window 100 by a spacer (not shown) that is formed from an insulation member.

Also, the RF antenna 40 may be installed in such a manner that a portion thereof is buried in the dielectric window 100, though not shown.

In addition, one or more power supply members (not shown) are installed for power supply to the RF antenna 40, and RF power (not shown) is connected to these power supply members via a matcher (not shown).

During the plasma processing, RF power for induced electric field formation, e.g., RF power having a frequency of 13.56 MHz may be applied from the

RF power source to the RF antenna 40. As such, induced electric field is formed in the main container 10 by the RF antenna 40 to which the RF power is applied, and a processing gas is changed to plasma by the induced electric field. The output power of the RF power source is appropriately set to be a value sufficient to generate plasma.

The dielectric window 100 is a component that forms the upper window of the main container 10 and forms induced electric field below the dielectric window 100 by the RF power application of the RF antenna 40 that is installed over the dielectric window 100.

The dielectric window 100 may be installed in singularity or desirably, in plurality, and may be formed from ceramic such as Al₂O₃, quartz or the like.

According to an embodiment, the dielectric window 100 may have a plan view corresponding to a rectangle and be installed in plurality, the edges of a plurality of dielectric windows 100 may be supported by a supporting member 230 so that the plurality of dielectric windows 100 may be arranged in a lattice pattern, and the dielectric windows may be installed at the upper end of the main container 10.

The supporting member 230 is a component for supporting the dielectric window 100, desirably has metallic material of high strength, and according to the supporting structure for the dielectric window 100 various embodiments for the supporting member 230 may be possible.

Instead of metallic material, the supporting member 230 may have the same or the similar material with the dielectric window 100, i.e. ceramic, quartz, etc.

Here a metallic member 231 may be attached to the upper surface in order to reinforce the strength.

The present invention is characterized in that a gas injecting structure is installed at at least a portion of the dielectric window 100 to be capable of performing the injecting control of processing gas on the substrate to be processed to be capable of performing uniform substrate processing.

That is, the structure of the ICP processing apparatus according to an embodiment of the present invention is characterized in that it includes a first diffusion plate 210 that firstly diffuses the processing gas and is connected with a processing gas supplying pipe 300, and a second diffusion plate 220 that diffuses the processing gas diffused by the first diffusion plate 210 into the main container 10 and is installed under the first diffusion plate 210, and the second diffusion plate 220 is formed at at least a part of the lower surface of the dielectric windows 100.

The first diffusion plate 210 is a component that firstly diffuses the processing gas and is connected with a processing gas supplying pipe 300.

According to an embodiment, the first diffusion plate 210 may have the same materials as the dielectric windows 100, and may be formed in one body with dielectric windows 100, or the separate member.

And the first diffusion plate 210 is formed with a plurality of first diffusion holes 211 in order to diffuse the processing gas.

The second diffusion plate 220 is a component that diffuses the processing gas diffused by the first diffusion plate 210 into the main container 10 and is installed under the first diffusion plate 210.

According to an embodiment, the second diffusion plate 220 may have the same material as the dielectric window 100, and may be formed in one body with the dielectric windows 100, or the separate member.

In addition, the second diffusion plate 220 is formed with a plurality of second diffusion holes 221 so that processing gas may be diffused into the main container 10.

Considering that the processing gas is diffused into the main container 10, it is desirable that the inner diameter of the second diffusion hole 221 is less than that of the first diffusion hole 211.

The second diffusion plate 220 may be bonded to the dielectric windows 100 by the similar manner with the first diffusion plate 210, by the various methods such as bolting, epoxy bonding, high-temperature bonding, ceramic bonding, or brazing (ceramic melting bonding).

The first diffusion plate 210 and the second diffusion plate 220 may have various embodiments according to an installation structure at the dielectric window 100.

According to an embodiment, as shown in FIG. 5, in at least a part of the plurality of the dielectric windows 100, the dielectric window 100 may be formed by all the first diffusion plate 210 and the second diffusion plate 220, and the first diffusion plate 210 and the second diffusion plate 220 may be installed having a gap with each other in an upper and lower direction

Concretely, the dielectric window 100 may be formed by laminating the first diffusion plate 210 and the second diffusion plate 220 in an upper and lower direction with each other.

In this case, a space where the processing gas passed through the first diffusion holes 211 of the first diffusion plate 210 is formed between the first diffusion plate 210 and the second diffusion plate 220.

According to another embodiment, as shown in FIGS. 1, 3, 4 and 6, in at least a part of the plurality of the dielectric windows 100, the second diffusion plate 220 may be formed in a part of the plane surface of the dielectric window 100.

Here, one of the first diffusion plate 210 and the second diffusion plate 220 may be integratedly formed with the dielectric window 100, and the first diffusion plate 210 and the second diffusion plate 220 are installed having a gap with each other in an upper and lower direction.

More concretely, various embodiments may be possible according to connecting structure of the first diffusion plate 210 and the second diffusion plate 220 with the dielectric window 100.

According to one embodiment, as shown in FIGS. 1, 3, and 5, the first diffusion plate 210 is integratedly formed with the dielectric window 100, and the second diffusion plate 220 is connected to the portion where the first diffusion plate 210 is formed in the dielectric window 100 as a separate member.

In this case, the first diffusion plate 210 may be bonded to the dielectric window 100 by the various methods such as bolting, epoxy bonding, high-temperature bonding, ceramic bonding, or brazing (ceramic melting bonding).

Since the aspect of the present invention has a feature in that smooth gas supply control for the gas to the inside of the main container 10 is achieved by installing gas supply structure in the dielectric window 100, various modifications are possible.

For example, referring to FIGS. 3 to 6, gas supply structures having the first diffusion plate 210 and the second diffusion plate 220, are described, but as one modified gas supply structure, in the modified gas supply structure, the processing gas supplied from the processing gas supplying pipe 300 may be diffused over the second diffusion plate 220, and injected to the inside of the main container 10 via the second diffusion holes 221 of the second diffusion plate 220 without the first diffusion plate 210.

Concretely, a though hole connected with the processing gas supplying pipe 300 is formed in the dielectric window 100, the second diffusion plate 220 may be installed to have a gap with the lower surface of the dielectric window 100 where the through hole is formed in order to form a diffusion space.

And the portion to which the second diffusion plate 220 is connected in the lower surface of the dielectric window 100 is formed as a groove so that the lower surfaces of the dielectric window 100 and the second diffusion plate 220 form a gentle surface with each other.

As the dielectric window 100 increases in size and is installed with the gas supply structure, the thickness thereof also relatively increases, which the vertical distance of the RF antenna with respect to the inside of the main container 10 increases. As a result, the applied power for the same induced electric field may increase.

Therefore, the dielectric window 100 may be formed with a groove 150 which is inserted with at least a portion of the RF antenna 40.

The groove 150 is a component which is formed in the dielectric window 100 in order to insert a portion of the RF antenna 40 in the groove 150, and various embodiments may be possible according to the shape and pattern of the antenna 40.

As the dielectric window 100 increases in size and is installed with the gas supply structure, the strength of the dielectric window 100 needs to be reinforced.

Therefore one or more ribs 240 having the same material as that of the dielectric window 100 may be formed at the upper surface of the dielectric window 100.

The rib 240 in the upper surface of the dielectric window 100 has the same material as the dielectric window 100, and the strength thereof is reinforced by being bonded by the various methods such as bolting, epoxy bonding, high-temperature bonding, ceramic bonding, or brazing (ceramic melting bonding).

It is possible to install the relatively thinner dielectric window 100 without deflection by the installation of the rib 240.

In the upper side of the first diffusion plate 210, a diffusion space forming member 320 that forms a processing gas diffusion space in which the processing gas is diffused in advance and is connected to a processing gas supply pipe 300, may be further installed.

The diffusion space forming member 320 is a component that diffuses the processing gas in advance and is connected to a processing gas supply pipe 300 in the upper side of the first diffusion plate 210.

Furthermore, a diffusion assistance member 310 for the processing gas diffusion formed with a plurality of injection holes 311 for injecting the processing gas into the processing gas diffusion space, the diffusion assistance member 310 being connected to the processing gas supply pipe 300, may be further installed.

The diffusion space forming member 320 and diffusion assistance member 310 can make uniform gas injection into the main container 10 by diffusing the processing gas in advance by the diffusion space forming member 320 and diffusion assistance member 310.

What is claimed is:

1. A gas supply structure for an inductively coupled plasma (ICP) processing apparatus that comprises
a main container 10 that houses a substrate to be processed S to perform plasma processing,
a substrate mounting unit 20 on which the substrate to be processed S is mounted in the main container 10,
an exhaust system 30 that discharges gas from inside of the main container 10,
one or more dielectric windows 100 that form an upper window of the main container 10, and
one or more RF antennas 40 which are installed to correspond to the dielectric windows 100 outside the main container 10 and to which RF power is applied to form induced electric field in the main container 10,
comprising
a first diffusion plate 210 that firstly diffuses the processing gas and is connected with a processing gas supplying pipe 300, and
a second diffusion plate 220 that diffuses the processing gas diffused by the first diffusion plate 210 into the main container 10 and is installed under the first diffusion plate 210,
wherein the second diffusion plate 220 is formed at at least a part of the lower surface of the dielectric windows 100.

2. The gas supply structure of claim 1, wherein a plurality of the dielectric windows 100 have a rectangular plane shape, and the plurality of the dielectric windows 100 are installed on the upper end of the main container 10 and the edges of the plurality of the dielectric windows 100 are supported by a supporting member 230 so that the plurality of the dielectric windows 100 are arranged in a lattice pattern.

3. The gas supply structure of claim 2, wherein in at least a part of the plurality of the dielectric windows 100, the dielectric window 100 is formed by all the first diffusion plate 210 and the second diffusion plate 220, and the first diffusion plate 210 and the second diffusion plate 220 are installed having a gap with each other in an upper and lower direction.

4. The gas supply structure of claim 1, wherein in at least a part of the plurality of the dielectric windows 100, the second diffusion plate 220 is formed in a part of the plane surface of the dielectric window 100.

5. The gas supply structure of claim 4, wherein one of the first diffusion plate 210 and the second diffusion plate 220 is integratedly formed with the dielectric window 100, and the first diffusion plate 210 and the second diffusion plate 220 are installed having a gap with each other in an upper and lower direction.

6. The gas supply structure of claim 1, wherein the dielectric window 100 is formed with a groove which is inserted with at least a portion of the RF antenna 40.

7. The gas supply structure of claim 1, wherein one or more ribs 240 having the same material as that of the dielectric window 100 are formed at the upper surface of the dielectric window 100.

8. The gas supply structure of claim 1, wherein a diffusion space forming member 320 that forms a processing gas diffusion space in which the processing gas is diffused in advance and is connected to a processing gas supply pipe 300, is further installed.

9. The gas supply structure of claim 8, wherein a diffusion assistance member 310 for the processing gas diffusion formed with a plurality of injection holes 311 for injecting the processing gas into the processing gas diffusion space, the diffusion assistance member 310 being connected to the processing gas supply pipe 300, is further installed.
